(19) United States
(12) Patent Application Publication
(10) Pub. No.: US 2012/0231571 A1
(43) Pub. Date: Sep. 13, 2012

(54) METHOD FOR PRODUCING A SOLAR CELL

(75) Inventors: Hideyo IIDA, Niigata-shi (JP); Toshiei Yamazaki, Niigata-shi (JP); Kenichi Sakata, Niigata-shi (JP)

(73) Assignee: NAMICS CORPORATION, Niigata-shi (JP)

(21) Appl. No.: 13/479,674

(22) Filed: May 24, 2012

Related U.S. Application Data
(63) Continuation of application No. 12/448,524, filed on Jun. 24, 2009.

(51) Int. Cl. H01L 31/0224; H01L 31/0232

(52) U.S. Cl. 438/72; 257/E31.127

(57) ABSTRACT

A method for producing a solar cell, including printing a conductive paste on a crystalline silicon substrate, and firing the conductive paste to form a light incident side electrode, wherein the conductive paste comprises conductive particles, glass frits, an organic binder and a solvent, wherein the conductive particles comprise (A) silver, and (B) one or more metals selected from the group consisting of copper, nickel, aluminum, zinc and tin, and the weight proportion (A):(B) is 5:95 to 90:10.

### CROSS-REFERENCE TO RELATED APPLICATIONS

This application is a continuation application of application Ser. No. 12/448,524 filed Jun. 24, 2009, which is the United States national phase application under 35 USC 371 of International application PCT/JP2006/325737 filed Dec. 25, 2006. The entire contents of each of application Ser. No. 12/448,524 and International application PCT/JP2006/325737 are hereby incorporated by reference herein.

### TECHNICAL FIELD

The present invention relates to a conductive paste for a solar cell, and in particular, relates to a conductive paste for the formation of an electrode for a crystalline silicon solar cell which utilize crystalline silicon such as single crystalline silicon or polycrystalline silicon as a substrate, and further relates to a solar cell provided with an electrode formed by firing the conductive paste.

### BACKGROUND ART

Crystalline silicon solar cells which use substrates of crystalline silicon obtained by processing single crystalline silicon or polycrystalline silicon into a flat plate shape, are recently seeing an increase to a large extent in the production. These solar cells have electrodes from which taking out electric power generated.

As an example, a cross-sectional schematic diagram of a crystalline silicon solar cell is presented in FIG. 1. A light incident side electrode 1 generally consists of bus electrodes and finger electrodes, and is focused by printing an electrode pattern of a conductive paste on an antireflection film 2 by a screen printing method or the like, and drying and firing the conductive paste. At the time of this firing, the light incident side electrode 1 can be formed to contact an n-type diffusion layer 3 formed on the surface of a crystalline silicon substrate 10 by making the conductive paste to fire through the antireflection film 2. Since light incidence does not have to occur from the back side of a p-type silicon substrate 4, a backside electrode 5 is formed over nearly the entire surface. A pn junction is formed at the interface between the p-type silicon substrate 4 and the n-type diffusion layer 3. Light such as solar light transmits through the antireflection film 2 and the n-type diffusion layer 3, and enters through the p-type silicon substrate 4, and during this process, light is absorbed so that electron-hole pairs are generated. These electron-hole pairs are separated by an electric field occurring at the pn junctions, with electrons being toward the light incident side electrode 1, while holes being toward the backside electrode 5. The electrons and holes are taken out to the outside as electric currents, through these electrodes.

In a crystalline silicon solar cell, the influence of electrodes on the characteristics of the solar cell, such as conversion efficiency, is large, and particularly the influence of the light incident side electrode is very large. This light incident side electrode is required to have sufficiently low contact resistance at the interface with the n-type diffusion layer, and to be in an ohmic electric contact. Furthermore, the electrical resistance of the electrode itself is needed to be sufficiently low, and it is also important that the resistance (conductor resistance) of the electrode material itself is low.

Also, in the case of the crystalline silicon solar cell shown in FIG. 1, generally, the optimal thickness of the n-type diffusion layer 3 is about 0.3 μm. Therefore, in regard to the formation of an electrode to the n-type diffusion layer 3, the thickness is required not to destroy the pn junctions, which are as shallow as about 0.3 μm.

Described above is an example of a crystalline silicon solar cell utilizing a p-type silicon substrate, but even in the case of using an n-type silicon substrate, a solar cell having a similar structure can be obtained only by employing a p-type diffusion layer, instead of the n-type diffusion layer for the p-type silicon substrate.

As an electrode material which fulfills the requirements of having low contact resistance and low conductor resistance, and not destroying shallow pn junctions, conductive pastes having silver as electrically conductive particles have been conventionally used. However, since silver is highly expensive and is a valuable material as a resource, in order to achieve cost reduction for electrodes, it is needed to reduce the proportion of use of silver in conductive pastes, or to substitute silver with an inexpensive metal other than silver. In recent years, as the amount of production of solar cells is rapidly increasing, a demand for cost reduction concerning the electrode materials for solar cells is growing stronger.

However, it is the current situation that no substantial development is implemented with regard to those conductive pastes which utilize conductive particles other than silver particles. For example, Patent Document 1 exemplifies conductive particles of copper, nickel and the like in addition to silver, but since silver particles are used in the pastes of specific embodiments, no description is given on the characteristics or the like of solar cells in the case of using conductive particles of copper, nickel and the like.

Patent Document 2 describes metallic additives such as Ti, Bi and Zn, but silver particles are used as conductive particles in the pastes of specific embodiments.

On the other hand, in the firing of the conductive pastes for electrode formation, firing in atmospheric air is preferred from the viewpoint of cost reduction. However, since metals other than noble metals are generally oxidized easily, firing in a reducing atmosphere is required, and there is also a problem that firing in atmospheric air is difficult.
Patent Document 1: Japanese Laid-open Patent [Kokai] Publication No. Hei 11-329070
Patent Document 2: Japanese Laid-open Patent [Kokai] Publication No. 2005-243500

### DISCLOSURE OF THE INVENTION

### Problems to be Solved by the Invention

An object of the present invention is to obtain a conductive paste for a solar cell, which is low in cost, and is capable of forming an electrode for a solar cell having an equal degree of contact resistance and ohmic electrical contact, as compared to conventional silver electrode pastes.

### Means for Solving the Problems

In the present invention, in order to realize a conductive paste for solar cells, particularly a conductive paste for crystalline silicon solar cells, which has a reduced amount of use of silver, investigation was devotedly conducted on a conductive paste composition which contains, in partial substitution of silver in the conductive paste, a plurality of metals having the possibility to be used in combination with silver. As a result, it was found that it is effective to use (A) silver, and (B) one selected from copper, nickel, aluminum, zinc and tin, or a combination of those.

That is, the present invention is a conductive paste for solar cells, including conductive particles, glass frits, an organic binder, and a solvent, wherein the conductive particles are formed from (A) silver, and (B) one or more selected from the group consisting of copper, nickel, aluminum, zinc and tin, and the weight proportion (A):(B) is 5:95 to 90:10. Preferably, the invention is a conductive paste in which component (B) is one or more selected from the group consisting of copper and nickel, and the weight proportion (A):(B) is 20:80 to 90:10. Also, preferably, the invention is a conductive paste in which the component (B) is zinc, and the weight proportion (A):(B) is 50:50 to 90:10. Furthermore, preferably, the invention is a conductive paste in which the component (B) is tin, and the weight proportion (A):(B) is 80:20 to 90:10. Preferably, the invention is a conductive paste in which the component (B) is one or more selected from the group consisting of copper and nickel, and one or more selected from the group consisting of aluminum, zinc and tin, and the weight proportion (A):(B) is 30:70 to 90:10. Also, preferably, the invention is a conductive paste in which the component (B) is one selected from the group consisting of copper and nickel, and one selected from the group consisting of aluminum and zinc, and the weight proportion (A):(B) is 20:80 to 90:10. Furthermore, the invention is a conductive paste in which the component (B) is one or more selected from the group consisting of copper and nickel in a proportion of 50% by weight or more.

Preferably, the invention is a conductive paste in which the conductive particles comprise particles of the component (A) and particles of a single element metal of the component (B). Also, preferably, the invention is a conductive paste in which the conductive particles comprise particles of the component (A) and particles of an alloy of the component (B). Furthermore, preferably, the invention is a conductive paste in which the conductive particles comprise particles of an alloy of the components (A) and (B). Also, preferably, the invention is a conductive paste in which the conductive particles comprise particles having a core formed from a single element or an alloy of the component (B), with the surface being coated with the component (A). More preferably, the invention is a conductive paste in which the component (B) in the conductive particles is one or more selected from the group consisting of copper and nickel. Also, preferably, the invention is a conductive paste in which the conductive paste is a conductive paste for the formation of electrodes for crystalline silicon solar cells.

In addition, the present invention is a crystalline silicon solar cell having an electrode formed by firing the conductive paste. Preferably, the invention is a crystalline silicon solar cell in which the electrode has an alloy layer formed at the part where metal particles of different elements are in contact. Also, preferably, the invention is a crystalline silicon solar cell further having a soldering pad part, in which the electrode and the soldering pad part are arranged to be in electrical contact. Furthermore, preferably, the invention is a crystalline silicon solar cell in which the electrode and a lead wire for electrically connecting a plurality of crystalline silicon solar cells, are connected with a conductive adhesive.

### Effects of the Invention

When the conductive paste for solar cells of the present invention is used, it is possible to form an electrode for a crystalline silicon solar cell, which is low in cost, and has an equal degree of contact resistance and ohmic electrical contact, as compared to conventional silver electrode pastes.

### BRIEF DESCRIPTION OF THE DRAWINGS

FIG. 1 is a cross-sectional schematic diagram of a crystalline silicon solar cell.

FIG. 2 is a schematic diagram of the light incident side surface of a solar cell having an electrode which utilizes the conductive paste of the present invention and a soldering pad part in arrangement, and cross-sectional views thereof.

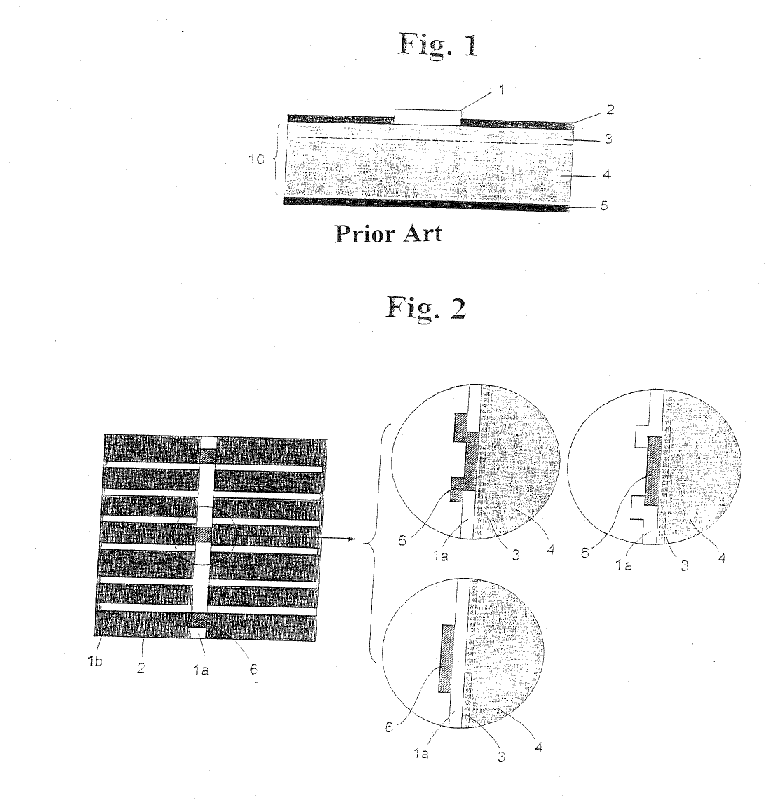

### REFERENCE NUMERALS

1 Light incident side electrode
1a Bus electrode
1b Finger electrode
2 Antireflection film
3 n-type diffusion layer
4 p-type silicon substrate
5 Backside electrode
6 Soldering pad part
10 Crystalline silicon substrate

### BEST MODE FOR CARRYING OUT THE INVENTION

In the present specification, the “crystalline silicon” comprises single crystalline or polycrystalline silicon. The “crystalline silicon substrate” means a material obtained by shaping crystalline silicon into a shape appropriate for device formation, such as a flat plate shape, for the formation of electric devices or electronic devices. As for the method for producing the crystalline silicon, any method may be used. For example, in the case of single crystalline silicon, the Czochralski method can be used, while in the case of polycrystalline silicon, a casting method can be used. Furthermore, a polycrystalline silicon ribbon produced by some other production method, for example, a ribbon pulling method, polycrystalline silicon formed on a heterogeneous substrate such as glass, and the like, can also be used as the crystalline silicon substrate. Furthermore, the “crystalline silicon solar cell” means a solar cell produced by using a crystalline silicon substrate. As an index indicating the solar cell performance, a fill factor (hereinafter, abbreviated to “FF”), which is obtainable from the measurement of the current-voltage characteristics under photo irradiation, is used.

In general, in the case where FF is 0.6 or greater, the solar cell can be said to have good performance. If FF is 0.65 or greater, the solar cell can be said to have better performance. Also, if FF is 0.7 or greater, the solar cell can be said to have even better performance.

The conductive paste of the present invention comprises conductive particles, a metal oxide, an organic binder, a solvent and glass fits, and is characterized in that the conductive particles contain (A) silver, and (B) one or more selected from the group consisting of copper, nickel, aluminum, zinc and tin. The conductive particles comprised in the conductive paste of the present invention are formed from the metals of components (A) and (B). However, the conductive paste may comprise impurities that are unavoidably incorporated. Also, within the scope of not impairing the effects of the present invention, the conductive paste may also comprise other metal particles. As for the metals described above, particles of a single element metal or particles of an alloy of these metals, and the like can be used.

The upper limit of the weight proportion of the component (B) in the conductive particles is 95% by weight, but the preferred upper limit may vary depending on the kind of the element selected from the component (B), or the structure of the particles. Also, from the viewpoint of reducing the use of highly expensive silver and decreasing the cost for the conductive paste, the weight proportion of the component (B) in the conductive particles is preferably 10% by weight or more, and more preferably 20% by weight or more. Therefore, the weight proportion (A):(B) is generally 5:95 to 90:10.

The metal of component (B) can be arbitrarily selected from copper, nickel, aluminum, zinc and tin, but it is preferable for the metal to comprise one or more selected from the group consisting of copper and nickel. Furthermore, the component (B) can further comprise, in addition to the one or more selected from the group consisting of copper and nickel, one or more selected from the group consisting of aluminum, zinc and tin. Particularly, from the viewpoint of cost reduction for the conductive paste, it is more preferable that the component (B) comprises copper and aluminum, and it is more preferable that the component (B) comprises an alloy of copper and aluminum.

Specifically, in the case where the component (B) in the conductive particles is one or more selected from the group consisting of copper and nickel, when the weight proportion of the component (B) in the conductive particles is in the range of 80% by weight or less, a favorable solar cell characteristic of FF being 0.6 or greater can be obtained. In this case, the weight ratio of copper and nickel can be set arbitrarily Also, in the case where the component (B) in the conductive particles is copper or nickel, when the weight proportion of the component (B) in the conductive particles is in the range of 80% by weight or less, a more favorable solar cell characteristic of FF being 0.7 or greater can be obtained.

In the case wherein the component (B) in the conductive particles is zinc, when the weight proportion of the component (B) in the conductive particles is in the range of 50% by weight or less, a favorable solar cell characteristic of FF being 0.7 or greater can be obtained.

In the case of the component (B) in the conductive particles is tin, the weight proportion of the component (B) in the conductive particles is in the range of 20% by weight or less, a favorable solar cell characteristic of FF being 0.65 or greater can be obtained. Also, when the weight proportion of tin is 10% by weight or less, a more favorable solar cell characteristic of FF being 0.7 or greater can be obtained.

The component (B) in the conductive particles can comprise, in addition to the one or more selected from the group consisting of copper and nickel, one or more metals selected from the group consisting of aluminum, zinc and tin. In this case, when the component (B) in the conductive particles is generally present in the range of 70 to 80% by weight or less, a favorable solar cell characteristic of FF being 0.6 or greater can be obtained. Furthermore, in order to obtain a favorable solar cell performance, it is preferable that the component (B) comprises one or more selected from the group consisting of copper and nickel in a proportion of 50% by weight or more.

Furthermore, preferably, the component (B) in the conductive particles comprises, in addition to the one selected from the group consisting of copper and nickel, one metal selected from the group consisting of aluminum, zinc and tin. In this case, when the component (B) in the conductive particles is present in the range of 70 to 80% by weight or less, a favorable solar cell characteristic of FF being 0.65 or greater can be obtained. In this case, it is more preferable that the component (B) comprises one selected from the group consisting of copper and nickel in a proportion of 50% by weight or more.

More preferably, in the case where the component (B) in the conductive particles comprises, in addition to the one selected from the group consisting of copper and nickel, one metal selected from the group consisting of aluminum and zinc, when the component (B) in the conductive particles is present in the range of 80% by weight or less, a favorable solar cell characteristic of FF being 0.65 or greater can be obtained. In this case, it is more preferable that the component (B) comprises one selected from the group consisting of copper and nickel in a proportion of 50% by weight or more.

Specifically, when the component (B) in the conductive particles is copper and aluminum, in the case where the weight ratio of copper and aluminum is 80:20, and the proportion of aluminum is less than that, if the weight proportion of the component (B) in the conductive particles is in the range of 80% by weight or less, a favorable solar cell characteristic can be obtained. It is more preferable that the weight ratio of copper and aluminum is 90:10, and the proportion of aluminum is less than that.

When the component (B) in the conductive particles consists of nickel and aluminum, in the case where the weight ratio of nickel and aluminum is 40:60, and the proportion of aluminum is less than that, if the weight proportion of the component (B) in the conductive particles is in the range of 80% by weight or less, and preferably 70% by weight or less, a favorable solar cell characteristic can be obtained. It is more preferable that the weight ratio of nickel and aluminum is 50:50, and the proportion of aluminum is less than that.

Furthermore, when the component (B) in the conductive particles consists of copper and zinc, in the case where the weight ratio of copper and zinc is 80:20, and the proportion of zinc is less than that, if the weight proportion of the component (B) in the conductive particles is in the range of 80% by weight or less, a favorable solar cell characteristic can be obtained. It is preferable that the weight ratio of copper and zinc is 90:10, and the proportion of zinc is less than that.

When the component (B) in the conductive particles consists of nickel and zinc, in the case where the weight ratio of nickel and zinc is 70:30, and the proportion of zinc is less than that, if the weight proportion of the component (B) in the conductive particles is in the range of 80% by weight or less, and preferably 70% by weight or less, a favorable solar cell characteristic can be obtained. It is preferable that the weight ratio of nickel and zinc is 80:20, and the proportion of zinc is less than that.

When the component (B) in the conductive particles consists of copper and tin, in the case where the weight ratio of copper and tin is 60:40, and the proportion of tin is less than that, if the weight proportion of the component (B) in the conductive particles is in the range of 70% by weight or less, and preferably 50% by weight or less, a favorable solar cell characteristic can be obtained. It is preferable that the weight ratio of copper and tin is 70:30, and the proportion of tin is less than that.

Furthermore, when the component (B) in the conductive particles consists of nickel and tin, in the case where the weight ratio of nickel and tin is 70:30, and the proportion of tin is less than that, if the weight proportion of the component (B) in the conductive particles is in the range of 70% by weight or less, and preferably 50% by weight or less, a favorable solar cell characteristic can be obtained. It is preferable that the weight ratio of nickel and tin is 80:20, and the proportion of tin is less than that.

The particle shape and particle dimension of the conductive particles are not particularly limited. As for the particle shape, for example, a spherical shape and a scale shape can be used. The particle dimension means the dimension of the maximum length part of a single particle. The particle dimension is preferably 0.05 to 20 μm, and more preferably 0.1 to 5 μm, from the viewpoint of workability and the like. In general, since the dimension of micro particles has a certain distribution, not all particles need to have the aforementioned particle dimension, and it is preferable that the particle dimension of the 50% cumulative value (D50) of all particles be in the above-mentioned range of particle dimension. Furthermore, the mean value of the particle dimension (average particle dimension) may also be in the above-described range.

In regard to the components (A) and (B) incorporated in the conductive particles, materials in a particulate form can be used. In that situation, the conductive particles can comprise particles of the component (A) and particles of a single element metal of the component (B). In this case, if the component (B) is a single element, a mixture of metal particles composed of a single element and particles of (A) silver, can be used as the conductive particles. Furthermore, if the component (B) is a plurality of elements, a mixture of plural kinds of metal particles respectively consisting of single elements and particles of (A) silver can be used as the conductive particles.

Also, in the case where the component (B) is a plurality of elements, it is preferable to use alloy particles formed from an alloy of a plurality of elements. In this case, a mixture of the alloy particles of the component (B) and particles of (A) silver is used as the conductive particles.

Furthermore, particles of an alloy of (A) silver and a single or a plurality of the elements of the component (B) can also be used as the conductive particles. In addition, the alloy particles can be produced according to an atomization method or a gas phase method, using metals consisting of plural kinds of single metal elements, as the raw material. The atomization method is a method of obtaining an alloy by melting a plurality of metals mixed at a predetermined composition at high temperature, and spraying the molten mixture together with water at high pressure. The gas phase method is a method for obtaining particles of an alloy in the gas phase by simultaneously vaporizing a plurality of metals. The former method allows obtaining of alloy particles having a relatively large particle dimension of about 1 to 50 μm, while the latter method is suitable for obtaining alloy particles having a relatively small particle dimension of 1 μm or less. According to these methods, particles having an arbitrary alloy composition and having an almost uniform concentration distribution over the entire particles, can be produced. Therefore, in the case of using alloy particles as the conductive particles in the conductive paste of the present invention, it is preferable to produce the particles by the atomization method or the gas phase method.

It is more preferable to use particles having a core formed from a single element metal or a metal alloy of the component (B), with the surface being coated with (A) silver, as the conductive particles. For example, particles having a core formed from copper or nickel, with the surface being coated with silver, can be used as the conductive particles. Furthermore, it is more preferable that the core is formed from an alloy of copper and nickel, an alloy of copper and aluminum, or the like. In the case where the conductive paste comprises conductive particles having this structure, the effects of the present invention can be exerted even in the case where the weight proportion of (A) silver is smaller. It is conceived that it is because the small amount of silver on the surface establishes a good electrical contact with crystalline silicon, and the metal forming the core merely takes the role of contributing to conductivity. For that reason, the upper limit of the weight proportion of the component (B) in the conductive particles is 95% by weight, preferably 90% by weight, and more preferably 85% by weight. However, since forming a thick coating of (A) silver on the core surface results in an increase in the production costs, the amount of silver used for coating is 5 to 50% by weight, preferably 10 to 50% by weight, and more preferably 15 to 30% by weight. The coating of silver can be performed using a wet plating method. The particle dimension of the conductive particles coated with silver can be set to, for example, 0.5 to 10 μm.

Furthermore, the various particles described above can be combined and used as the conductive particles. Also, in addition to the conductive particles combining the various particles, particles of (A) silver may further be added according to necessity.

It is preferable that the conductive paste of the present invention further contain at least one metal oxide selected from zinc oxide (ZnO), copper oxide (Cu₂O, CuO), titanium oxide (TiO₂), tin oxide (SnO₂) and the like, in view of obtaining stable and satisfactory electrode performance. It is conceived that the metal oxide controls the sinterability of the conductive particles in the firing process, or controls expansion of liquefied glass fits, and contributing to obtaining a contact between the conductive particles and the semiconductor surface. The shape of the metal oxide is not particularly limited, and a spherical type, an amorphous type or the like can be used. The particle dimension is not particularly limited, but is preferably 0.1 to 5 μm from the viewpoint of dispersibility. In general, the dimension of micro particles has a certain distribution, not all particles need to have the above-mentioned particle dimension, and it is preferable that the particle dimension of the 50% cumulative value of all particles (D50) be in the above-mentioned range of particle dimension. Furthermore, the mean value of the particle dimension (average particle dimension) may also be in the above-mentioned range. The amount of addition of the metal oxide is preferably 0.1 to 20 parts by weight, and more preferably 1 to 10 parts by weight, relative to 100 parts by weight of the conductive particles.

The organic binder and the solvent take the role of adjusting the viscosity of the conductive paste, or the like, and thus both of them are not particularly limited. The organic binder can also be used after dissolving in the solvent.

As the organic binder, cellulose-based resins (for example, ethyl cellulose, nitrocellulose, and the like) and (meth)acrylic resins (for example, polymethyl acrylate, polymethyl methacrylate, and the like) can be used. The amount of addition of the organic binder is usually 1 to 10 parts by weight, and preferably 1 to 4 parts by weight, relative to 100 parts by weight of the conductive particles.

As the solvent, alcohols (for example, terpineol, α-terpineol, β-terpineol, and the like) and esters (for example, hydroxyl group-containing esters, 2,2,4-trimethyl-1,3-pentanediol monoisobutyrate, butylcarbitol acetate, and the like) can be used. The amount of addition of the solvent is usually 0.5 to 20 parts by weight, and preferably 10 to 20 parts by weight, relative to 100 parts by weight of the conductive particles.

As for the glass fits, Pb-based glass fits (for example, PbO—B₂O₃—SiO₂ family, and the like), and Pb-free glass frits (for example, Bi₂O₃—B₂O₃—SiO₂—CeO₂—LiO₂—NaO₂ family and the like) can be used, but the examples are not limited to these. The shape of the glass frits is not particularly limited, and for example, a spherical shape, an amorphous type, or the like can be used. Furthermore, the particle dimension is also not particularly limited, but from the viewpoint of workability or the like, the mean value of the particle dimension (average particle dimension) is preferably in the range of 0.01 to 10 μm, and more preferably in the range of 0.05 to 1 μm. The amount of addition is usually 0.1 to 10 parts by weight, and preferably 1 to 5 parts by weight, relative to 100 parts by weight of the conductive particles.

Moreover, the conductive paste of the present invention can be incorporated, if necessary, with a plasticizer, a defoaming agent, a dispersant, a leveling agent, a stabilizer, an adhesion promoting agent, and the like as additives. Among these, as for the plasticizer, phthalic acid esters, glycolic acid esters, phosphoric acid esters, sebacic acid esters, adipic acid esters, citric acid esters, and the like can be used.

The method for producing the conductive paste of the present invention involves production by adding conductive particles to an organic binder and a solvent, and further adding, as necessary, a metal oxide and glass frits, followed by mixing and further dispersing the components.

The mixing is performed with, for example, a planetary mixer. Furthermore, the dispersing can be performed by a three roll mill. The mixing and dispersing are not limited to these methods, and various existing methods can be used.

The conductive paste of the present invention is particularly preferably a conductive paste for the formation of electrodes for crystalline silicon solar cells. Therefore, it is preferable that a crystalline silicon solar cell have an electrode obtainable by firing the conductive paste of the present invention.

An electrode formed by using the conductive paste of the present invention may face a problem that soldering to the electrode is difficult. In such a situation, this problem can be solved by adopting a structure of arranging the soldering pad part, which enables soldering, to be in electrical contact with the electrode, as shown in FIG. 2. In FIG. 2, the light incident side electrode consists of a bus electrode 1a and a finger electrode 1b, but the soldering pad part 6 is arranged to be in electrical contact with the bus electrode 1a. As shown by the three types of cross-sectional structures in FIG. 2, the formation of the soldering pad part 6 may be carried out such that the soldering pad part is first formed and then the electrode is formed, or may also be carried out in a reverse order. In addition, the bus electrode 1a, the finger electrode 1b and the soldering pad part 6 can be formed to be in contact with the n-type diffusion layer 3, since the conductive paste is allowed to fire through the antireflection film during firing the conductive paste.

Alternatively, a lead wire for electrically connecting a plurality of crystalline silicon solar cells, can be connected to the electrode by means of a conductive adhesive. The conductive adhesive is not particularly limited, and can be produced by, for example, providing a mixture of an epoxy resin and a phenolic resin at a weight ratio of 6:4, adding an imidazole as a curing catalyst in an amount of 2% by weight of the total resin content, adding silver particles to a content of 80% by weight of the total weight of the conductive adhesive, and dispersing the mixture with a three roll mill. Furthermore, it is also acceptable to add copper particles in place of silver particles, to the same resin blend.

The method for producing a solar cell using the conductive paste of the present invention, will be described by taking the case of a crystalline silicon solar cell utilizing a p-type silicon substrate, as an example. First, the conductive paste of the present invention is printed on a crystalline silicon substrate having an n-diffusion layer or on an antireflection film formed on the n-diffusion layer of a crystalline silicon substrate, by a method such as a screen printing method, and the paste is dried at a temperature of about 100 to 150° C. for several minutes. Similarly, a conductive paste for p-type silicon semiconductor is printed on the back side over nearly the entire surface, and is dried. Subsequently, the assembly is fired using a furnace such as a tubular furnace in atmospheric air at a temperature of about 500 to 850° C. for several minutes, to form a light incident side electrode and a backside electrode. In this firing process, particularly in the case where the conductive paste of the present invention comprises particles of the component (A) and particles of a single element metal of the component (B), the respective particles are sintered while forming a layer of an alloy of the components (A) and (B) at the part where the particles are in contact, and thus an electrode having low conductor resistance can be formed. Also, in the case where the component (B) is a plurality of single elemental metal particles, an alloy layer can be formed at the part where the particles of the component (A) and the particles of the respective kinds of the component (B) are in contact. Furthermore, in that situation, an alloy layer can be formed at the part where the metal particles of different kinds of the component (B) are in contact. Therefore, when an alloy layer is formed at the part where metal particles of different elements are in contact, an electrode having even lower conductor resistance can be formed. In the case where a conductive paste having a predetermined composition is printed on an antireflection film, the electrode and the silicon substrate can be electrically connected in order to allow the high temperature paste material to fire through the antireflection film during the process of firing. In addition, the firing conditions are not limited to the conditions as described above, and can be appropriately selected.

Even for a solar cell having a structure of entire backside electrode type (so-called a back contact structure), or a structure in which the light incident side electrode is conducted to the back side through a through-hole provided in the substrate, an electrode can be formed using the conductive paste of the present invention.

An example of a solar cell utilizing a p-type silicon substrate has been described above, but also even in the case of a crystalline silicon solar cell utilizing an n-type silicon substrate, a solar cell can be produced by a similar process using the conductive paste of the present invention, except for the difference that the impurities for forming a diffusion layer are changed from n-type impurities such as phosphorus, to p-type impurities such as boron, and a p-type diffusion layer is formed instead of an n-type diffusion layer. Furthermore, even in the case of using any of a single crystalline silicon substrate or a polycrystalline silicon substrate, the conductive paste of the present invention can be used to exert the effects of the present invention.

### EXAMPLES

Hereinafter, the present invention will be described in detail by way of Examples, but the present invention is not intended to be limited to these.

### Example 1

For the conductive paste for experiment of Example 1, the components indicated in Table 1 and Table 2 were used. The components other than the conductive particles were maintained consistent as shown in Table 1, and the metals in the conductive particles were provided at the composition as shown in Table 2. Furthermore, as shown in Table 2, a solar cell which utilized 100% silver conductive particles, was also produced for each examination of composition, for comparison. The conductive paste was prepared by mixing these components with a planetary mixer, further dispersing the mixture with a three roll mill, and making a paste.

Evaluation of the conductive paste of the present invention was carried out by fabricating solar cells by using the respective conductive pastes of Examples and Comparative Examples, and measuring the characteristics. The method of fabricating solar cells is as follows.

As the crystalline silicon substrate, a substrate of the Czochralski (CZ) method, a diameter of 3 inches, a (001) plane, B-doped p-type single crystalline silicon substrate, specific resistance of about 3 Ω·cm, and a substrate thickness of 200 μm, was used.

First, a silicon oxide layer having a thickness of about 20 μm was formed on the substrate by dry oxidation, and then the layer was etched with a solution prepared by mixing hydrogen fluoride, pure water and ammonium fluoride, to eliminate damages on the surface of the substrate. Furthermore, washing of heavy metals was performed using an aqueous solution containing hydrochloric acid and hydrogen peroxide.

Subsequently, a pyramidal textured structure was formed on one side by a wet etching method (aqueous solution of sodium hydroxide), and then the structure was washed with an aqueous solution containing hydrochloric acid and hydrogen peroxide.

Subsequently, phosphorus was diffused according to a diffusion method, using phosphorus oxychloride (POCl₃), at a temperature of 1000° C. for 20 minutes, to form an n-type diffusion layer having a depth of about 0.3 μm.

Subsequently, a mixed gas of NH₃/SiH₄=0.5 was subjected to glow discharge decomposition at 1 Ton (133 Pa), and thereby, a silicon nitride film (antireflection film) having a film thickness of about 70 nm was formed by a plasma CVD method. After this, the substrate was cut with a dicer to 15 mm squares, and thus cell substrates were obtained.

For the formation of a light incident side electrode, the respective conductive pastes of the Examples and Comparative Examples were each screen printed on the antireflection film made of a silicon nitride film of the cell substrate, using a 250-mesh screen mask made of stainless steel. At this time, a screen mask pattern which consists of a bus electrode and a finger electrode was used, the screen printing was conducted so that the film thickness of the conductive paste would be about 20 μm. Thereafter, the conductive paste was dried at 150° C. for one minute.

Subsequently, for the formation of a backside electrode, a conductive paste containing aluminum particles, glass frits, ethyl cellulose and a solvent as the main components was printed on the back side over nearly the entire surface by a screen printing method, and the conductive paste was dried at 150° C. for 1 minute.

Thereafter, using a tubular furnace capable of controlling various atmospheres, the cell substrate was fired in atmospheric air at a temperature of 700° C. for 1 to 2 minutes, to form a light incident side electrode and a backside electrode, and thus a solar cell was obtained.

The current-voltage characteristics of the solar cells thus produced were measured under irradiation of a solar simulator light (AM1.5, energy density 100 mW/cm²), and FF was calculated from the measurement results. The measurement results are presented in Table 2. As it is obvious from this table, when the proportion of copper particles or nickel particles in the conductive particles was in the range of 80% by weight or less, a favorable solar cell characteristic of FF being 0.7 or greater could be obtained. Furthermore, in the cases where the proportion of zinc particles in the conductive particles was 50% by weight or less, and the proportion of tin particles was 10% by weight or less, a favorable solar cell characteristic of FF being 0.7 or greater could be obtained. Also, in the case where the proportion of tin particles was 20% by weight or less, a favorable solar cell characteristic of FF being 0.65 or greater could be obtained.

In the current Example, borosilicate-based lead glass was used as the glass flits, but even in the case where lead-free glass frits which did not contain lead oxide were used, high FF values of 0.7 or greater could be obtained, similarly to the results described above.

TABLE 1

| | | Composition |
|---|---|---|
| | | (parts by |
| Type | Component | weight) |
| Conductive | Sum of (A) and (B) | 100 |
| particle | | |
| Organic binder | Ethyl cellulose | 3 |
| Solvent | 2,2,4-Trimethyl-1,3-pentadiol | 13 |
| | monoisobutyrate | |
| Glass frits | Lead borosilicate-based glass | 2.5 |
| | (amorphous, average particle | |
| | dimension 0.1 μm) | |
| Additive | ZnO | 3.5 |

TABLE 2

| | | Experiment No. | | | | |
|---|---|---|---|---|---|---|
| | | 1-1 | 1-2 | 1-3 | | |
| (B) | | Copper | Nickel | Zinc | 1-4 | 1-5 |
| Proportion | Proportion | Fill | Fill | Fill | Aluminum | Tin |
| of (B) | of silver | factor | factor | factor | Fill factor | Fill factor |
| (wt %) | (wt %) | (FF) | (FF) | (FF) | (FF) | (FF) |
| 0 | 100 | 0.752 | 0.755 | 0.769 | 0.732 | 0.739 |
| 0.04 | 99.96 | — | — | — | 0.625 | |
| 10 | 90 | 0.761 | 0.768 | 0.762 | 0.247 | 0.704 |
| 20 | 80 | 0.772 | 0.749 | 0.715 | 0.219 | 0.698 |
| 30 | 70 | 0.754 | 0.771 | 0.762 | 0 | 0.487 |
| 50 | 50 | 0.76 | 0.769 | 0.743 | 0 | 0.353 |
| 70 | 30 | 0.741 | 0.751 | 0.273 | 0 | 0 |
| 80 | 20 | 0.702 | 0.709 | 0.272 | 0 | 0 |
| 90 | 10 | 0.311 | 0.392 | — | 0 | 0 |
| 100 | 0 | 0 | 0 | — | 0 | 0 |

(In the diagram, “—” indicates that no measurement value was obtained.)
Copper particles (manufactured by Mitsui Mining & Smelting Co., Ltd.): spherical, average particle dimension 3 μm
Nickel particles (manufactured by Toho Titanium Co., Ltd.): average particle dimension 1 μm
Zinc particles (manufactured by Honjo Chemical Corp.): average particle dimension 10 μm
Aluminum particles (manufactured by Yamaishi Metal Co., Ltd.): average particle dimension 10 μm
Tin particles (manufactured by Yamaishi Metal Co., Ltd.): average particle dimension 3 μm

### Example 2

For the conductive paste of Example 1, two kinds of metals which were selected from (B) indicated in Table 3 instead of the metals of Example 1, were alloyed to obtain the weight proportions indicated in Table 3, and the alloy was made into particles and used. For the respective alloy particles, particles produced according to the atomization method were mainly used, and particles having an average particle dimension of about 10 μm to 50 μm were used.

These metal alloy particles were mixed with silver particles at the proportions indicated in Table 4, and the mixture was used as the conductive particles. These conductive particles were used to prepare conductive pastes. Subsequently, the conductive pastes were used in the fabrication of solar cells in the same manner as in Example 1, the current-voltage characteristics were measured, and FF was calculated from the measurement results. The obtained FF values are presented in Table 4. As it is obvious from Table 4, when the total proportion of the component (B) in the conductive particles is approximately in the range of 70 to 80% by weight or less, a favorable solar cell characteristic of FF being 0.7 or greater could be obtained.

Specifically, in the case where the component (B) was Cu and Al, and where their weight ratio was 90:10 (Experiment No. 2-1), when the proportion of these metals in the conductive particles was in the range of 80% by weight or less, a favorable solar cell characteristic of FF being 0.7 or greater could be obtained. It is clear that favorable solar cell characteristics can be obtained when the metal other than silver, which is contained in the conductive particles in Example 1, is only Cu. Furthermore, the difference in the composition of about 10% does not exert that much influence to the solar cell characteristics. Therefore, it became clear that in the case where the weight ratio of Cu and Al is 80:20, and preferably 90:10, and the proportion of Al is lower than that, if the weight proportion of these metals in the conductive particles is in the range of 80% by weight or less, favorable solar cell characteristics can be obtained.

Similarly, as can be seen from the results of Experiment No. 2-2, it became clear that in the case where the component (B) is Ni and Al, and where the weight ratio of Ni and Al is 40:60, and preferably 50:50, and the proportion of Al is lower than that, if the weight proportion of the component (B) in the conductive particles is in the range of 70% by weight or less, a favorable solar cell characteristic of FF being 0.7 or greater can be obtained. It also became clear that if the proportion is in the range of 80% by weight or less, a favorable solar cell characteristic of FF being 0.65 or greater can be obtained.

Similarly, as can be seen from the results of Experiment No. 2-3, it became clear that in the case where the weight ratio of Cu and Zn is 80:20, and preferably 90:10, and the proportion of Zn is lower than that, if the weight proportion of the component (B) in the conductive particles is in the range of 80% by weight or less, favorable solar cell characteristics can be obtained.

Similarly, as can be seen from the results of Experiment No. 2-4, it became clear that in the case where the weight ratio of Ni and Zn is 70:30, and preferably 80:20, and the proportion of Zn is lower than that, if the weight proportion of the component (B) in the conductive particles is in the range of 70% by weight or less, a favorable solar cell characteristic of FF being 0.7 or greater can be obtained. It also became clear that if the proportion of the component (B) in the conductive particles is in the range of 80% by weight or less, a favorable solar cell characteristic of FF being 0.65 or greater can be obtained.

Similarly, as can be seen from the results of Experiment No. 2-5, it became clear that in the case where the weight ratio of Cu and Sn is 60:40, and preferably 70:30, and the proportion of Sn is lower than that, if the weight proportion of the component (B) in the conductive particles is in the range of 50% by weight or less, a favorable solar cell characteristic of FF being 0.7 or greater can be obtained. It also became clear that if the proportion of the component (B) in the conductive particles is in the range of 70% by weight or less, a favorable solar cell characteristic of FF being 0.65 or greater can be obtained.

Similarly, as can be seen from the results of Experiment No. 2-6, it became clear that in the case where the weight ratio of Ni and Sn is 70:30, and preferably 80:20, and the proportion of Sn is lower than that, if the weight proportion of the component (B) in the conductive particles is in the range of 50% by weight or less, a favorable solar cell characteristic of FF being 0.7 or greater can be obtained. It also became clear that if the proportion of the component (B) in the conductive particles is in the range of 70% by weight or less, a favorable solar cell characteristic of FF being 0.65 or greater can be obtained.

Similarly, as can be seen from the results of Experiment No. 2-7, it became clear that in the case where the weight ratio of Cu and Ni is 70:30, if the weight proportion of the component (B) in the conductive particles is in the range of 70% by weight or less, a favorable solar cell characteristic of FF being 0.7 or greater can be obtained. Therefore, it became clear that when Cu and Ni are used in combination, and the weight proportion of the component (B) in the conductive particles is in the range of 70% by weight or less, favorable solar cell characteristics can be obtained.

TABLE 3
Unit: wt %

| Com- | Experiment No. | | | | | | |
|---|---|---|---|---|---|---|---|
| po- | 2-1 | 2-2 | 2-3 | 2-4 | 2-5 | 2-6 | 2-7 |
| sition | Cu—Al | Ni—Al | Cu—Zn | Ni—Zn | Cu—Sn | Ni—Sn | Ni—Cu |
| Cu | 90 | | 90 | | 70 | | 70 |
| Ni | | 50 | | 80 | | 80 | 30 |
| Zn | | | 10 | 20 | | | |
| Al | 10 | 50 | | | | | |
| Sn | | | | | 30 | 20 | |

TABLE 4

| | | Experiment No. | | | | | | |
|---|---|---|---|---|---|---|---|---|
| | | 2-1 | 2-2 | 2-3 | 2-4 | 2-5 | 2-6 | 2-7 |
| Total | | Cu—Al | Ni—Al | Cu—Zn | Ni—Zn | Cu—Sn | Ni—Sn | Ni—Cu |
| proportion | Proportion | Fill | Fill | Fill | Fill | Fill | Fill | Fill |
| of (B) | of (A) | Factor | Factor | Factor | Factor | Factor | Factor | Factor |
| (wt %) | (wt %) | (FF) | (FF) | (FF) | (FF) | (FF) | (FF) | (FF) |
| 0 | 100 | 0.77 | 0.733 | 0.75 | 0.734 | 0.756 | 0.742 | 0.775 |
| 10 | 90 | 0.77 | 0.739 | 0.725 | 0.731 | 0.739 | 0.758 | 0.773 |
| 20 | 80 | 0.773 | 0.771 | 0.745 | 0.763 | 0.724 | 0.739 | 0.77 |
| 30 | 70 | 0.762 | 0.758 | 0.735 | 0.767 | 0.718 | 0.731 | 0.761 |
| 50 | 50 | 0.759 | 0.751 | 0.718 | 0.759 | 0.711 | 0.724 | 0.76 |
| 70 | 30 | 0.751 | 0.709 | 0.707 | 0.728 | 0.692 | 0.683 | 0.744 |
| 80 | 20 | 0.712 | 0.652 | 0.705 | 0.688 | 0.487 | 0.413 | 0.603 |
| 90 | 30 | 0.439 | 0.238 | 0.368 | 0.382 | 0.232 | 0.218 | 0.411 |
| 100 | 0 | 0 | 0 | 0.212 | 0.218 | 0 | 0 | 0 |

### Example 3

Conductive pastes were prepared in which metal particles coated with silver, as shown in Table 5, were used as the conductive particles, instead of the conductive particles of Example 1 for the conductive pastes of Example 1. These conductive paste were used to fabricate solar cells in the same manner as in Example 1, the current-voltage characteristics were measured, and FF was calculated from the measurement results. The obtained FF values are presented in Table 5. Therefore, when the method of coating metal particles of the component (B) with silver was used, even in the case where the weight proportion of the component (B) in the conductive particles was about 85% by weight, favorable solar cell characteristics were obtained.

TABLE 5

| Type of conductive particles | FF |
|---|---|
| 10 parts of silver particles (Ag 100%) + 90 parts of silver-coated | 0.763 |
| copper particles (Ag 15%) | |
| 100 parts of silver-coated copper particles (Ag 15%) | 0.748 |
| 10 parts of silver (Ag 100%) + 90 parts of silver-coated nickel | 0.767 |
| particles (Ag 15%) | |
| 100 parts of silver-coated nickel particles (Ag 15%) | 0.733 |

### Example 4

To solve the problem related to solderability of the conductive paste of the present invention, an experiment was performed to implement connection between solar cells using a soldering pad part capable of soldering and a conductive adhesive.

The results of tensile strength tests for three types of connections, such as soldered connection via a soldering pad part with a firing type silver paste, connection using a silver conductive adhesive, and connection using a copper conductive adhesive, were compared with the tensile strength in the case of a silver electrode produced using a conductive paste which did not comprise any metal other than silver.

The firing type silver paste for forming a soldering pad part was produced by dispersing ethyl cellulose, glass and silver particles (weight ratio 4:2:100) with a three roll mill (paste A).

The conductive adhesive was produced by providing a mixture of epoxy resin:phenol resin (weight ratio 6:4), adding an imidazole as a curing catalyst in an amount of 2% by weight of the total resin content, adding silver particles to a content of 80% by weight of the total weight of the conductive adhesive, and dispersing the resulting mixture with a three roll mill (paste B). A paste C was produced in the same manner as in the case of paste B, except that copper particles were used instead of silver particles.

Initially, a conductive paste of the present invention which comprised conductive particles composed of 70 parts by weight of an alloy of Cu (70% by weight)-Al (30% by weight) and 30 parts by weight of silver, was used to form a bus electrode on the same single crystalline silicon substrate as that used in Example 1. Subsequently, onto this bus electrode, the pastes A, B and C were printed to a size of 2 mm×12 mm After a soldering pad part was formed by firing the pastes A at a high temperature of 700° C., flux was coated, a solder drawn copper ribbon wire (2 mm in width, thickness 250 μm) was mounted, and soldering was performed at 250° C. for one minute. For the pastes B and C, after coating and before drying, a copper ribbon wire was placed on each of the pastes sized to 2 mm×12 mm, and the paste was cured under a load of 200 g, at a temperature of 200° C. for 30 minutes. As a Comparative Example, measurement was made of the tensile strength for the case of using a conventional firing type silver-based electrode containing silver only as the conductive particles, and the tensile strength of each of the pastes was normalized on the basis of the aforementioned value for comparison. As it is obvious from the results shown in Table 6, in the case of using the pastes A, B and C, there could be obtained tensile strengths of an equal extent to that of the conventional structure, which was the Comparative Example.

TABLE 6

| | | | | Comparative |
|---|---|---|---|---|
| | Paste A | Paste B | Paste C | Example |
| Normalized | 0.95 | 0.93 | 0.91 | 1 |
| tensile | | | | |
| strength | | | | |

1. A method for producing a solar cell, comprising;
printing a conductive paste on a crystalline silicon substrate, and
firing the conductive paste to form a light incident side electrode,
wherein the conductive paste comprises conductive particles, glass frits, an organic binder and a solvent,
wherein the conductive particles comprise (A) silver, and
(B) one or more metals selected from the group consisting of copper, nickel, aluminum, zinc and tin, and
the weight proportion (A):(B) is 5:95 to 90:10.

2. The method according to claim 1, wherein the component (B) is one or more metals selected from the group consisting of copper and nickel, and
the weight proportion (A):(B) is 20:80 to 90:10.

3. The method according to claim 2, wherein the component (B) is nickel.

4. The method according to claim 1, wherein the component (B) is zinc, and
the weight proportion (A):(B) is 50:50 to 90:10.

5. The method according to claim 1, wherein the component (B) is tin, and
the weight proportion (A):(B) is 80:20 to 90:10.

6. The method according to claim 1, wherein the component (B) is one or more metals selected from the group consisting of copper and nickel, and one or more metals selected from the group consisting of aluminum, zinc and tin, and
the weight proportion (A):(B) is 30:70 to 90:10.

7. The method according to claim 1, wherein the component (B) is one or more metals selected from the group consisting of copper and nickel, and one or more metals selected from the group consisting of aluminum and zinc, and
the weight proportion (A):(B) is 20:80 to 90:10.

8. The method according to claim 1, wherein the component (B) comprises one or more metals selected from the group consisting of copper and nickel, in a proportion of 50% by weight or more.

9. The method according to claim 1, wherein the conductive particles comprise particles of the component (A) and particles of a single element metal of the component (B).

10. The method according to claim 1, wherein the conductive particles comprise particles of the component (A) and particles of an alloy of the component (B).

11. The method according to claim 1, wherein the conductive particles comprise particles of an alloy of the components (A) and (B).

12. The method according to claim 1, wherein the conductive particles comprise particles having a core formed from a single element or an alloy of the component (B) with the surface being coated with the component (A).

13. The method according to claim 12, wherein the component (B) of the conductive particles is one or more metals selected from the group consisting of copper and nickel.

14. The method according to claim 12, wherein the component (B) of the conductive particles is nickel.

15. The method according to claim 1, wherein the electrode has an alloy layer formed at the part where metal particles of different elements are in contact.

16. The method according to claim 1, further comprising forming a soldering pad part, wherein an electrode and the soldering pad part are arranged to be in electrical contact.

17. The method according to claim 1, further comprising;
printing a conductive paste for a p-type silicon semiconductor on the back side over nearly the entire surface of the crystalline silicon substrate and drying the conductive paste for a p-type silicon semiconductor, before firing the conductive paste to form an electrode,
wherein firing the conductive paste comprises firing the conductive paste to form an light incident side electrode and firing the conductive paste for the p-type silicon semiconductor to form a backside electrode,
wherein the crystalline silicon substrate is a p-type silicon substrate with an antireflection film formed on a n-diffusion layer of the crystalline silicon substrate, and the conductive paste is printed on the antireflection film on the crystalline silicon substrate.
